(19) United States
(12) Patent Application Publication
(10) Pub. No.: US 2024/0063074 A1
(43) Pub. Date: Feb. 22, 2024

(54) SEMICONDUCTOR PACKAGES AND METHODS OF MANUFACTURING THEREOF

(71) Applicant: Taiwan Semiconductor Manufacturing Company, Ltd., Hsinchu (TW)

(72) Inventors: Po-Yu Chen, Baoshan Township (TW); Yu Hsiang Chen, Hsinchu City (TW); Cheng Hung Wu, Hsinchu County (TW); Wei-Pin Changchien, Taichung City (TW); Ming-Fa Chen, Taichung City (TW)

(73) Assignee: Taiwan Semiconductor Manufacturing Company, Ltd., Hsinchu (TW)

(21) Appl. No.: 17/889,868

(22) Filed: Aug. 17, 2022

(51) Int. Cl. H01L 23/367; H01L 23/473; H01L 23/373; H01L 25/065; H01L 25/00; H01L 23/00

(52) U.S. Cl. CPC H01L 23/367; H01L 23/473; H01L 23/3732; H01L 23/3736; H01L 23/3738; H01L 23/373; H01L 25/0657; H01L 25/50; H01L 24/32; H01L 2224/32245; H01L 2224/29124; H01L 2224/29147; H01L 2224/29105; H01L 2224/29117; H01L 2224/29144; H01L 2224/2916; H01L 2224/29123; H01L 2224/29155; H01L 2224/29169; H01L 2224/29139; H01L 2224/29166; H01L 2224/29184; H01L 2224/29118; H01L 2224/29138; H01L 2224/29193; H01L 2224/29186; H01L 24/29; H01L 2224/08145; H01L 24/08; H01L 2224/16145; H01L 24/16; H01L 2224/73204; H01L 2224/73253; H01L 24/73

(57) ABSTRACT

A semiconductor package is disclosed. The semiconductor package includes a package substrate. The semiconductor package includes a semiconductor die having a first surface attached to the package substrate and a second surface. The semiconductor package includes a heat sink attached to the second surface of the semiconductor die. The semiconductor package includes a heat dissipation layer interposed between the heat sink and the semiconductor die. The heat dissipation layer comprises one or more high-k dielectric materials.

### BACKGROUND

The semiconductor industry has experienced rapid growth due to continuous improvement in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-nanometer node), which allows more components to be integrated into a given area. As the demand for miniaturization, higher speed, and greater bandwidth, as well as lower power consumption and latency has grown recently, there has grown a need for smaller and more creative packaging techniques for semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a semiconductor package, in accordance with some embodiments.

FIG. 2 illustrates a cross-sectional view of a portion of an example implementation of the semiconductor package of FIG. 1, in accordance with some embodiments.

FIG. 3 illustrates a cross-sectional view of a portion of another example implementation of the semiconductor package of FIG. 1, in accordance with some embodiments.

FIGS. 4, 5, 6, 7, 8, and 9 illustrate top views of various patterns in which heat dissipation structures of the disclosed heat dissipation layer are formed, in accordance with some embodiments.

FIGS. 10 and 11 illustrate perspective views of various examples of the disclosed heat dissipation layer, in accordance with some embodiments.

FIG. 12 illustrates a perspective view of yet another example of the disclosed heat dissipation layer, in accordance with some embodiments.

FIG. 13 is an example flow chart of a method for fabricating a semiconductor package, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As semiconductor technologies further advance, packaged semiconductor devices, e.g., three-dimensional integrated circuits (3DICs), have emerged as an effective alternative to further reduce the physical size of semiconductor devices. In a packaged (e.g., stacked) semiconductor device, active circuits such as logic, memory, processor circuits, and the like are fabricated on different semiconductor wafers or dies. Two or more these semiconductor dies may be placed side-by-side or stacked on top of one another to further reduce the form factor of the semiconductor device.

While various aspects of performance (e.g., electrical performance) of a semiconductor package with its semiconductor dies placed in this way can be significantly improved, other issues may arise. For example, in such a semiconductor package, heat (e.g., generated by respective active devices of the semiconductor dies) typically tend to be localized in a limited number of spots (sometimes referred to as heat spots) across the package. This is generally due to the lack of a heat dissipation path for the heat to propagate in multiple directions, which can disadvantageously compromise some of the supposedly decent performance. Thus, the existing semiconductor packages have not been entirely satisfactory in many aspects.

The present disclosure provides various embodiments of a semiconductor package including one or more semiconductor dies coupled to a heat dissipation layer, and methods of forming the same. In various embodiments, the heat dissipation layer can provide additional heat dissipation path(s) for the coupled semiconductor dies, so as to spread the relatively localized heat spots in the existing semiconductor packages over a wider area. As such, the heat generated by the functioning semiconductor dies can be more quickly dissipated, which should advantageously and significantly improve every aspect of the package's performance. For example, the heat dissipation layer, as disclosed herein, can include a material that is characterized with a relatively high thermal conductivity, e.g., a high-k dielectric material. In another example, the disclosed heat dissipation layer can include other materials with a high thermal conductivity, e.g., water; silicon; carbon nanotubes; diamond; boron nitride (BₓA_{y}), titanium nitride (TiₓN_{y}), titanium oxide (TiOₓ), silicon carbide (SiₓC_{y}), aluminum nitride (AlₓN_{y}); aluminum; copper; gallium; germanium; gold; iron; magnesium; nickel; platina; silver; titanium; tungsten; zinc; or combinations thereof.

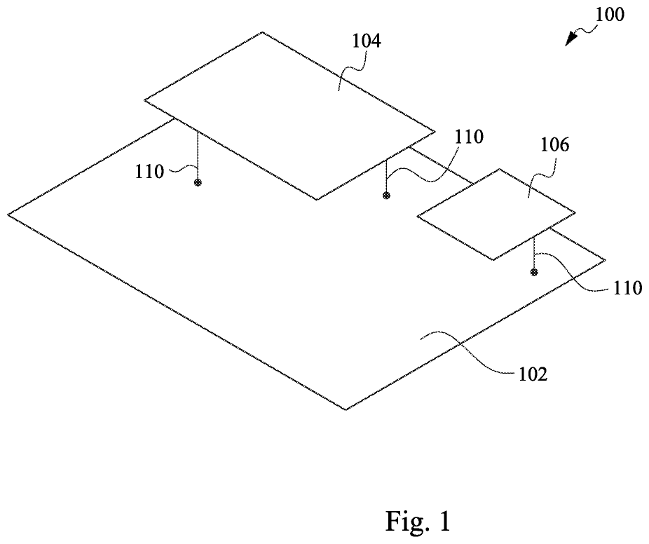

FIG. 1 illustrates a schematic diagram of a semiconductor package 100 includes a number of semiconductor dies (or chips) 102, 104, and 106, in accordance with various embodiments. As shown, three semiconductor dies 102 to 106 are integrated with each other as a (e.g., three-dimensional (3D)) system package, e.g., a System on Integrated Chips (SoIC). However, it should be understood that the semiconductor package 100 can include any number of integrated semiconductor dies and those semiconductor dies can be integrated in any of various other arrangements, while remaining within the scope of present disclosure.

In various embodiments, each of the semiconductor dies 102 to 106 may be configured as a partitioned system (e.g., a System on Chip (SoC)) with a certain function. Further, through the use of various advanced interconnection technologies (e.g., 110 of FIG. 1), the semiconductor dies 102 to 106 can have respectively different chip sizes, respectively different functions, and/or be respectively fabricated with different technology nodes, which advantageously allows the semiconductor package 100 to have ultra-low link latency and ultra-low energy consumption. For example, the semiconductor die 102 may function as a logic system, while the semiconductor dies 104 and 106 may function as a memory system and a sensor system, respectively. In another example, the semiconductor die 102 may function as a logic system, while the semiconductor dies 104 and 106 may function as a first memory system and a second memory system, respectively.

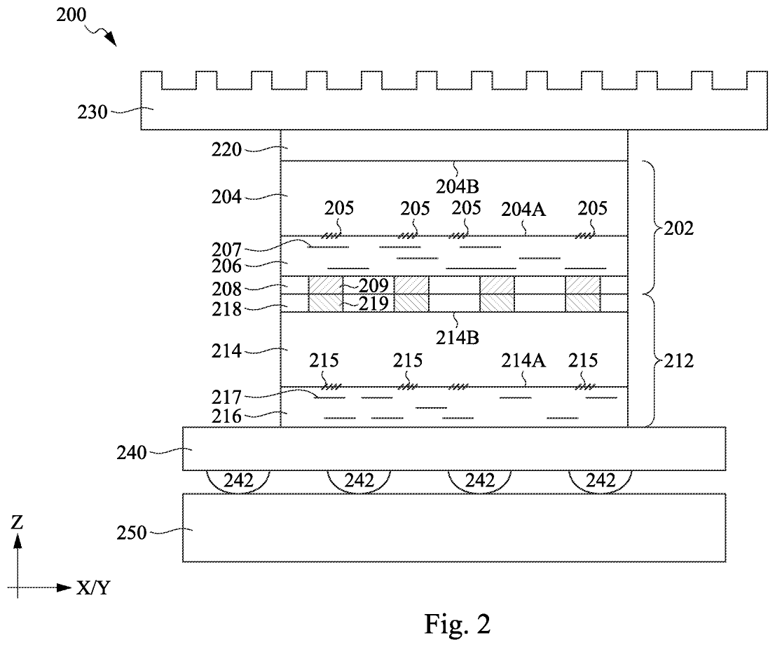

FIG. 2 illustrates a cross-sectional view of an example of the semiconductor package 100 shown in FIG. 1 (hereinafter “package 200”), in accordance with various embodiments of the present disclosure. It should be appreciated that the example package 200 of FIG. 2 is merely an illustrative embodiment, and is not intended to limit the scope of present disclosure. Hence, the illustrative embodiment of FIG. 2 can include various of other components (e.g., an interposer, one or more through silicon/substrate via (TSV) structures, one or more dummy dies, an underfill material, an encapsulant material, etc.), while remaining within the scope of present disclosure. As shown in the cross-sectional view of FIG. 2, the package 200 includes semiconductor dies 202 and 212, each of which can be an implementation of any of the semiconductor dies 102 to 106 shown in FIG. 1.

As shown, the semiconductor die 202 includes a substrate 204, a number of active and/or passive device features 205 (e.g., transistors, resistors, capacitors, etc.) formed along a frontside surface 204A of the substrate, and a number of metallization layers 206 formed over the device features. Each of the metallization layers 206 can include a number of conductive lines and a number of conductive vias, which are collectively referred to as interconnect structures 207. In some embodiments, the conductive lines are each formed as a conductive (e.g., metal) structure extending along a lateral direction (e.g., the X direction or the Y direction), and the conductive vias are each formed as a conductive (e.g., metal) structure extending along a vertical direction (e.g., the Z direction). Some of the device features 205 can be operatively coupled to each other (through a respective group of the interconnect structures 207) so as to provide a respective function (e.g., a Boolean logic function), which may sometimes be referred to as a cell. Similarly, the semiconductor die 212 also includes a substrate 214, a number of active and/or passive device features 215 (e.g., transistors, resistors, capacitors, etc.) formed along a frontside surface 214A of the substrate, and a number of metallization layers 216 formed over the device features. Each of the metallization layers 216 also includes a number of conductive lines and a number of conductive vias, which are collectively referred to as interconnect structures 217.

In various embodiments, the semiconductor die 202 is integrated (e.g., bonded) to the semiconductor die 212 through various bump structures or through a bumpless bond. The bonding may be hybrid bonding, fusion bonding, direct bonding, dielectric bonding, metal bonding, solder joints (e.g., microbumps), or the like. For example, the semiconductor die 202 (sometimes referred to as a top die) and semiconductor die 212 (sometimes referred to as a bottom die) are face-to-back (F2B) bonded, in which a frontside of the top die 202 faces a backside of the bottom die 212. In such embodiments, the semiconductor die 202 may include a bonding layer 208 with a number of bonding structures (e.g., bonding vias) 209 and the semiconductor die 212 may include a bonding layer 218 with a number of bonding structures (e.g., bonding vias) 219, wherein each of the bonding structures 209 is (e.g., physically and/or electrically) connected to a corresponding one of the bonding structures 219. The bonding layer 208 may be formed on the frontside (e.g., 204A) of the substrate 204, and the bonding layer 218 may be formed on the backside (e.g., 214B) of the substrate 214.

Further, on a backside surface 204B of the substrate 204 (the semiconductor die 202), the package 200 can include a heat sink 230 attached thereto. The heat sink 230 can be configured to dissipate at least some of the heat generated during operation of the package 200, for example, the heat generated by the device features 205 and/or 215. Further on the frontside surface 214A of the substrate 214 (the semiconductor die 212), the package 200 can optionally include a redistribution structure 240 configured to reroute or redistribute interconnect structures of the package 200. Such rerouted interconnect structures can be coupled to a number of conductive connectors 242 for the package 200. The connectors 242 may be implemented as solder balls, metal pillars, controlled collapse chip connection (C4) bumps, micro bumps, electroless nickel-electroless palladium-immersion gold technique (ENEPIG) formed bumps, combination thereof (e.g., a metal pillar having a solder ball attached thereof), or the like.

The connectors 242 can further connect the bonded dies 202 and 212 to a package substrate 250. The package substrate 250 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. The package substrate 250 may be an interposer. Additionally, the package substrate 250 may be a SOI substrate. Generally, an SOI substrate includes a layer of a semiconductor material such as epitaxial silicon, germanium, silicon germanium, SOI, silicon germanium on insulator (SGOI), or combinations thereof. The package substrate 250 is, in one alternative embodiment, based on an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the package substrate 250. In some embodiments, with respect to the package (bottom) substrate 250, the heat sink 230 may sometimes be referred to as a (top) package substrate.

In accordance with various embodiments of the present disclosure, the package 200 includes a heat dissipation layer 220 interposed between the top die 202 and the heat sink 230. The heat dissipation layer 220 can have a relatively high thermal conductivity which allows a significant amount of the heat generated by the device features 205 and/or 215 to spread laterally (e.g., along the X and/or Y direction). In this way, the heat can be more quickly and efficiently dissipated through the heat sink 230. Advantageously, the intended (e.g., electrical) performance of the semiconductor dies 202-212 will not be compromised.

In some embodiments, the heat dissipation layer 220 can be formed as a homogeneous layer. For example, the heat dissipation layer 220 can have a material with a high thermal conductivity such as, a high-k dielectric material; water; silicon; carbon nanotubes; diamond; boron nitride (BₓN_{y}), titanium nitride (TiₓN_{y}), titanium oxide (TiOₓ), silicon carbide (SiₓC_{y}), aluminum nitride (AlₓN_{y}); aluminum; copper; gallium; germanium; gold; iron; magnesium; nickel; platina; silver; titanium; tungsten; zinc; or combinations thereof. The high-k dielectric material include, but are not limited to, hafnium silicate, zirconium silicate, hafnium dioxide and zirconium dioxide, which are typically deposited using atomic layer deposition (ALD). In some other embodiments, the heat dissipation layer 220 can be formed as heterogeneous layer. As such, the heat dissipation layer 220 can include a combination of at least two of the above-listed materials.

In some embodiments, the heat dissipation layer 220 has at least a portion of each of its surfaces in physical contact with the heat sink 230 or the coupled die (top die 202 in the example of FIG. 2). In the example where the heat dissipation layer 220 is formed as a homogeneous layer, the heat dissipation layer 220 can have side boundaries of the homogeneous material (e.g., a high-k dielectric material) aligned with the coupled die, as shown in FIG. 2. Stated another way, the heat dissipation layer 220 can occupy a substantially similar area to the coupled die. Alternatively, the heat dissipation layer 220 can occupy a larger or smaller area than the coupled die. In the example where the heat dissipation layer 220 is formed as a heterogeneous layer, the heat dissipation layer 220 can have side boundaries of one of the heterogeneous materials aligned with the coupled die. Such a heat dissipation layer 220 can have a number of (heat dissipation) structures penetrating through one of the heterogeneous materials, with each of the heat dissipation structures formed of another of the heterogeneous materials and physically (therefore thermally) connecting the coupled die to the heat sink, which will be discussed below.

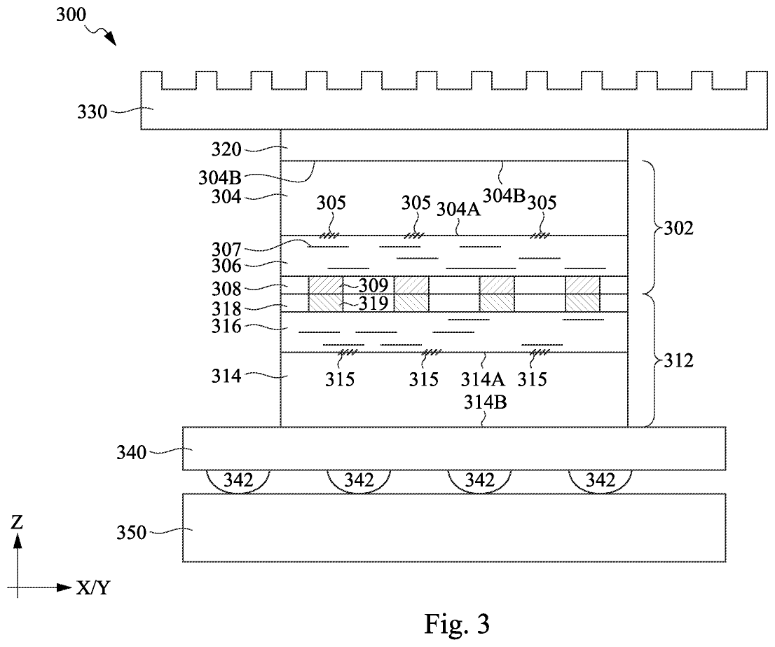

FIG. 3 illustrates a cross-sectional view of another example of the semiconductor package 100 shown in FIG. 1 (hereinafter “package 300”), in accordance with various embodiments of the present disclosure. It should be appreciated that the example package 300 of FIG. 3 is merely an illustrative embodiment, and is not intended to limit the scope of present disclosure. Hence, the illustrative embodiment of FIG. 3 can include various of other components (e.g., an interposer, one or more through silicon/substrate via (TSV) structures, one or more dummy dies, an underfill material, an encapsulant material, etc.), while remaining within the scope of present disclosure. As shown in the cross-sectional view of FIG. 3, the package 300 includes semiconductor dies 302 and 312, each of which can be an implementation of any of the semiconductor dies 102 to 106 shown in FIG. 1.

As shown, the semiconductor die 302 includes a substrate 304, a number of active and/or passive device features 305 (e.g., transistors, resistors, capacitors, etc.) formed along a frontside surface 304A of the substrate, and a number of metallization layers 306 formed over the device features. Each of the metallization layers 306 can include a number of conductive lines and a number of conductive vias, which are collectively referred to as interconnect structures 307. In some embodiments, the conductive lines are each formed as a conductive (e.g., metal) structure extending along a lateral direction (e.g., the X direction or the Y direction), and the conductive vias are each formed as a conductive (e.g., metal) structure extending along a vertical direction (e.g., the Z direction). Some of the device features 305 can be operatively coupled to each other (through a respective group of the interconnect structures 307) so as to provide a respective function (e.g., a Boolean logic function), which may sometimes be referred to as a cell. Similarly, the semiconductor die 312 also includes a substrate 314, a number of active and/or passive device features 315 (e.g., transistors, resistors, capacitors, etc.) formed along a frontside surface 314A of the substrate, and a number of metallization layers 316 formed over the device features. Each of the metallization layers 316 also includes a number of conductive lines and a number of conductive vias, which are collectively referred to as interconnect structures 317.

In various embodiments, the semiconductor die 302 is integrated (e.g., bonded) to the semiconductor die 312 through various bump structures or through a bumpless bond. The bonding may be hybrid bonding, fusion bonding, direct bonding, dielectric bonding, metal bonding, solder joints (e.g., microbumps), or the like. For example, the semiconductor die 302 (sometimes referred to as a top die) and semiconductor die 312 (sometimes referred to as a bottom die) are face-to-face (F2F) bonded, in which a frontside of the top die 302 faces a frontside of the bottom die 312. In such embodiments, the semiconductor die 302 may include a bonding layer 308 with a number of bonding structures (e.g., bonding vias) 309 and the semiconductor die 312 may include a bonding layer 318 with a number of bonding structures (e.g., bonding vias) 319, wherein each of the bonding structures 309 is (e.g., physically and/or electrically) connected to a corresponding one of the bonding structures 319. The bonding layer 308 may be formed on the frontside (e.g., 304A) of the substrate 304, and the bonding layer 318 may also be formed on the frontside (e.g., 314A) of the substrate 314.

Further, on a backside surface 304B of the substrate 304 (the semiconductor die 302), the package 300 can include a heat sink 330 attached thereto. The heat sink 330 can be configured to dissipate at least some of the heat generated during operation of the package 300, for example, the heat generated by the device features 305 and/or 315. Further on a backside surface 314B of the substrate 314 (the semiconductor die 312), the package 300 can optionally include a redistribution structure 340 configured to reroute or redistribute interconnect structures of the package 300. Such rerouted interconnect structures can be coupled to a number of conductive connectors 342 for the package 300. The connectors 342 may be implemented as solder balls, metal pillars, controlled collapse chip connection (C4) bumps, micro bumps, electroless nickel-electroless palladium-immersion gold technique (ENEPIG) formed bumps, combination thereof (e.g., a metal pillar having a solder ball attached thereof), or the like.

The connectors 342 can further connect the bonded dies 302 and 312 to a package substrate 350. The package substrate 350 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. The package substrate 350 may be an interposer. Additionally, the package substrate 350 may be a SOI substrate. Generally, an SOI substrate includes a layer of a semiconductor material such as epitaxial silicon, germanium, silicon germanium, SOI, silicon germanium on insulator (SGOI), or combinations thereof. The package substrate 350 is, in one alternative embodiment, based on an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the package substrate 350. In some embodiments, with respect to the package (bottom) substrate 350, the heat sink 330 may sometimes be referred to as a (top) package substrate.

In accordance with various embodiments of the present disclosure, the package 300 also includes a heat dissipation layer 320 interposed between the top die 302 and the heat sink 330. Similar to the heat dissipation layer 220, the heat dissipation layer 320 can have a relatively high thermal conductivity which allows a significant amount of the heat generated by the device features 305 and/or 315 to spread laterally (e.g., along the X and/or Y direction). In this way, the heat can be more quickly and efficiently dissipated through the heat sink 330. Advantageously, the intended (e.g., electrical) performance of the semiconductor dies 302-312 will not be compromised.

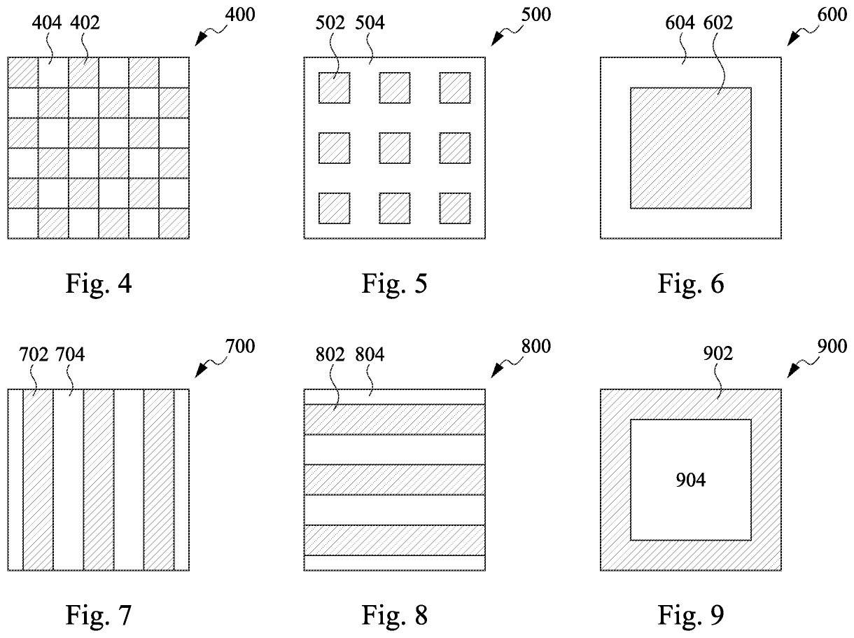

FIGS. 4, 5, 6, 7, 8, and 9 illustrate a number of example patterns 400, 500, 600, 700, 800, and 900, in which the disclosed heat dissipation structures (e.g., of the heat dissipation layer 220/320) are formed, in accordance with various embodiments of the present disclosure. The patterns 400 to 900 are illustrated from the top view of a corresponding heat dissipation layer, and thus, it should be understood that each of the heat dissipation structures formed within the heat dissipation layer has a top surface and a bottom surface in physical contact with a heat sink and a couple die, respectively. As such, the heat dissipation structures can help propagate the heat generated by the coupled die to the heat sink.

In FIG. 4, the pattern 400 includes a number of heat dissipation structures 402 arranged with one another as a checkboard. Specifically, the heat dissipation structures 402 are each formed as a block, with each of its four sides abutted to a material 404. The block 402 (heat dissipation structures 402) can be formed of at least one of the above-listed materials with a high thermal conductivity (e.g., a high-k dielectric material), while the material 404 can include another one of the above-listed materials with a high thermal conductivity or a material not listed above (e.g., a low-k dielectric material).

In FIG. 5, the pattern 500 includes a number of heat dissipation structures 502 arranged with one another as an array. Specifically, the heat dissipation structures 502 are formed as a number of respective blocks spaced apart from one another with a material 504. The block 502 (heat dissipation structures 502) can be formed of at least one of the above-listed materials with a high thermal conductivity (e.g., a high-k dielectric material), while the material 504 can include another one of the above-listed materials with a high thermal conductivity or a material not listed above (e.g., a low-k dielectric material).

In FIG. 6, the pattern 600 includes a single heat dissipation structure 602 surrounded by a material 604. The heat dissipation structure 602 may sometimes be referred to as a pillar structure. The heat dissipation structures 602 can be formed of at least one of the above-listed materials with a high thermal conductivity (e.g., a high-k dielectric material), while the material 604 can include another one of the above-listed materials with a high thermal conductivity or a material not listed above (e.g., a low-k dielectric material).

In FIG. 7, the pattern 700 includes a number of heat dissipation structures 702 arranged with one another in parallel. Specifically, the heat dissipation structures 702 are formed as a number of respective stripes extending along a first lateral direction and spaced apart from one another with a material 704. The stripe 702 (heat dissipation structures 702) can be formed of at least one of the above-listed materials with a high thermal conductivity (e.g., a high-k dielectric material), while the material 704 can include another one of the above-listed materials with a high thermal conductivity or a material not listed above (e.g., a low-k dielectric material).

In FIG. 8, the pattern 800 includes a number of heat dissipation structures 802 arranged with one another in parallel. Specifically, the heat dissipation structures 802 are formed as a number of respective stripes extending along a second lateral direction and spaced apart from one another with a material 804. The stripe 802 (heat dissipation structures 802) can be formed of at least one of the above-listed materials with a high thermal conductivity (e.g., a high-k dielectric material), while the material 804 can include another one of the above-listed materials with a high thermal conductivity or a material not listed above (e.g., a low-k dielectric material).

In FIG. 9, the pattern 900 includes a single heat dissipation structure 902 surrounding a material 904. The heat dissipation structure 902 may sometimes be referred to as a ring structure. The heat dissipation structures 902 can be formed of at least one of the above-listed materials with a high thermal conductivity (e.g., a high-k dielectric material), while the material 904 can include another one of the above-listed materials with a high thermal conductivity or a material not listed above (e.g., a low-k dielectric material).

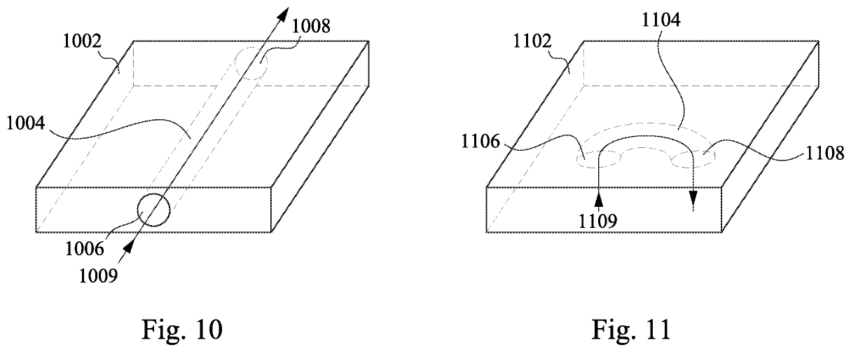

FIGS. 10 and 11 illustrate perspective views of other examples of the disclosed heat dissipation layer (e.g., 220, 320), in accordance with various embodiments of the present disclosure. In FIGS. 10 and 11, heat dissipation layers 1002 and 1102 each include at least one fluid tunnel that allows fluid (e.g., water) to flow therethrough from an inlet to an outlet in directions 1009 and 1109, respectively. In some embodiments, the fluid tunnel can extend through the corresponding heat dissipation layer formed of at least one of the above-listed materials with a high thermal conductivity (e.g., a high-k dielectric material).

For example in FIG. 10, the heat dissipation layer 1002 includes a tunnel 1004 extending from an inlet 1006 to an outlet 1008. The inlet 1006 and outlet 1008 are formed as openings on sidewalls of the heat dissipation layer 1002, respectively. Thus, it should be understood that neither the inlet 1006 nor the outlet 1008 is in contact with a heat sink that is in contact with a top surface of the heat dissipation layer 1002 or a die that is in contact with a bottom surface of the heat dissipation layer 1002. With such a configuration, fluid (e.g., water) can flow through the tunnel 1004 to further dissipate the heat. For example in FIG. 11, the heat dissipation layer 1102 includes a tunnel 1104 extending from an inlet 1106 to an outlet 1108. The inlet 1106 and outlet 1108 are formed as openings on a bottom surface of the heat dissipation layer 1102, respectively.

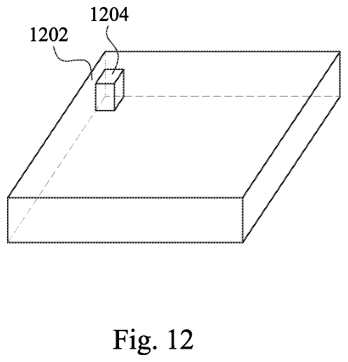

FIG. 12 illustrates a perspective view of yet another example of the disclosed heat dissipation layer (e.g., 220, 320), in accordance with various embodiments of the present disclosure. In FIG. 12, heat dissipation layer 1202 is formed of at least one of the above-listed materials with a high thermal conductivity (e.g., a high-k dielectric material). Further, the heat dissipation layer 1202 includes a number of (heat dissipation) structures 1204, each of which is formed of one of the above-listed materials with a high thermal conductivity. In such an embodiment, while the heat dissipation layer 1202 may have its bottom surface and top surface in contact with a coupled die and a heat sink, respectively, the structure 1204 may have one or none of its top and bottom surfaces in contact with the coupled die or the heat sink. Alternatively stated, for a heat dissipation structure embedded in a heat dissipation layer, its top or bottom surface is not necessarily in contact with a coupled component.

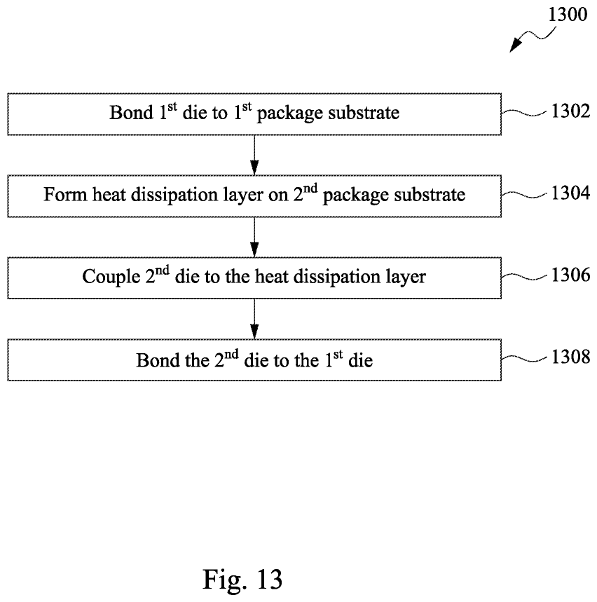

FIG. 13 illustrates a flow chart of an example method 1300 for forming at least a portion of a semiconductor package, in accordance with some embodiments. It should be noted that the method 1300 is merely an example, and is not intended to limit the present disclosure. Accordingly, it is understood that the order of operation of the method 1300 of FIG. 13 can change, that additional operations may be provided before, during, and after the method 1300 of FIG. 13, and that some other operations may be described briefly herein. For example, the semiconductor package may include a portion of the semiconductor packages 200-300, as discussed above. Accordingly, operations of the method 1300 may sometimes be discussed in conjunction with the components discussed with respect to the figures above.

The method 1300 starts with operation 1302 of bonding a first semiconductor die to a first package substrate. Using the package 200 of FIG. 2 as a representative example, the first semiconductor die (e.g., 212), which includes a substrate, a number of device features, a number of metallization layers, and at least one bonding layer, is bonded to the first package substrate (e.g., 250). In some embodiments, the first semiconductor die 212 can be bonded to the first package substrate 250 through a number of connectors (e.g., 242).

The method 1300 proceeds to operation 1304 of forming a heat dissipation layer on a second package substrate. Continuing with the above example, the heat dissipation layer (e.g., 220) may be formed as a homogeneous or heterogeneous layer over the second package substrate (e.g., 230). That is, the heat dissipation layer can include one or more of the following materials that are each characterized with a relatively high thermal conductivity, e.g., a high-k dielectric material; water; silicon; carbon nanotubes; diamond; boron nitride (BₓA_{y}), titanium nitride (TiₓN_{y}), titanium oxide (TiOₓ), silicon carbide (SiₓC_{y}), aluminum nitride (AlₓN_{y}); aluminum; copper; gallium; germanium; gold; iron; magnesium; nickel; platina; silver; titanium; tungsten; zinc; or combinations thereof.

The method 1300 proceeds to operation 1306 of coupling a second semiconductor die to the heat dissipation layer. Continuing with the above example, the second semiconductor die (e.g., 202) may be formed over the heat dissipation layer 220. The second semiconductor die 202 may be formed over (e.g., boned to) the heat dissipation layer 220 without a glue layer. In some embodiments, the heat dissipation layer 220 has at least a portion of its top/bottom surface in contact with the semiconductor die 202. Further, as discussed above, the heat dissipation layer 220 can include a number of heat dissipation structures partially or fully extending therethrough. With the heat dissipation structures fully extending through the layer, each of the heat dissipation structures may be formed of the above-listed high thermal conductivity material; and with the heat dissipation structures partially extending through the layer, each of the heat dissipation structures may not be necessarily formed of the above-listed high thermal conductivity material, in some embodiments.

The method 1300 proceeds to operation 1308 of bonding the second semiconductor die to the first semiconductor die. Continuing with the above example, the second semiconductor die 202 may be bonded to the first semiconductor die 212 through various bump structures or through a bumpless bond. The bonding may be hybrid bonding, fusion bonding, direct bonding, dielectric bonding, metal bonding, solder joints (e.g., microbumps), or the like.

In one aspect of the present disclosure, a semiconductor package is disclosed. The semiconductor package includes a package substrate. The semiconductor package includes a semiconductor die having a first surface attached to the package substrate and a second surface. The semiconductor package includes a heat sink coupled to the second surface of the semiconductor die. The semiconductor package includes a heat dissipation layer interposed between the heat sink and the semiconductor die. The heat dissipation layer comprises one or more high-k dielectric materials.

In another aspect of the present disclosure, a semiconductor package is disclosed. The semiconductor package includes a first package substrate. The semiconductor package includes a semiconductor die disposed on the first package substrate. The semiconductor package includes a heat dissipation layer disposed on the semiconductor die. The semiconductor package includes a second package substrate disposed on the heat dissipation layer. The heat dissipation layer comprises a plurality of structures, each of the plurality of structures being formed of a high-k dielectric material and having a first surface and a second surface in contact with the semiconductor die and the second package substrate, respectively.

In yet another aspect of the present disclosure, a method for fabricating semiconductor packages is disclosed. The method includes bonding one or more semiconductor dies to a first package substrate, wherein the first package substrate is on a first side of the one or more semiconductor dies. The method includes forming a heat dissipation layer on a second side of the one or more semiconductor dies. The heat dissipation layer comprises a plurality of structures, and wherein each of the plurality of structures is formed of a high-k dielectric material. The method includes coupling a second package substrate to the one or more semiconductor dies, with the heat dissipation layer interposed between the second package substrate and the one or more semiconductor dies. Each of the plurality of structures has a first surface and a second surface in contact with the one or more semiconductor dies and the second package substrate, respectively.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a package substrate;
a semiconductor die having a first surface attached to the package substrate and a second surface;
a heat sink coupled to the second surface of the semiconductor die; and
a heat dissipation layer interposed between the heat sink and the semiconductor die; and
wherein the heat dissipation layer comprises one or more high-k dielectric materials.

2. The semiconductor package of claim 1, wherein the heat dissipation layer includes a plurality of structures formed of the one or more high-k dielectric materials and penetrating through the heat dissipation layer.

3. The semiconductor package of claim 2, wherein, when viewed from the top, the plurality of structures form a checkboard pattern.

4. The semiconductor package of claim 2, wherein, when viewed from the top, the plurality of structures form a two-dimensional array scattered across the heat dissipation layer.

5. The semiconductor package of claim 2, wherein, when viewed from the top, the plurality of structures form a single pillar at a center of the heat dissipation layer.

6. The semiconductor package of claim 2, wherein, when viewed from the top, the plurality of structures form a number of pillars arranged in parallel and extending across the heat dissipation layer.

7. The semiconductor package of claim 2, wherein, when viewed from the top, the plurality of structures form a ring surrounding the heat dissipation layer.

8. The semiconductor package of claim 1, wherein the heat dissipation layer further comprises a fluid tunnel with an inlet and an outlet.

9. The semiconductor package of claim 8, wherein the inlet and outlet are formed on opposite sides of the heat dissipation layer, respectively.

10. The semiconductor package of claim 8, wherein the inlet and outlet are formed on a same side of the heat dissipation layer.

11. The semiconductor package of claim 1, wherein the heat dissipation layer further comprises a material selected from a group consisting of: water; silicon; carbon nanotubes; diamond; boron nitride (BₓA_{y}), titanium nitride (TiₓN_{y}), titanium oxide (TiOₓ), silicon carbide (SiₓC_{y}), aluminum nitride (AlₓN_{y}); aluminum; copper; gallium; germanium; gold; iron; magnesium; nickel; platina; silver; titanium; tungsten; zinc; and combinations thereof.

12. A semiconductor package, comprising:
a first package substrate;
a semiconductor die disposed on the first package substrate;
a heat dissipation layer disposed on the semiconductor die; and
a second package substrate disposed on the heat dissipation layer;
wherein the heat dissipation layer comprises a plurality of structures, each of the plurality of structures being formed of a high-k dielectric material and having a first surface and a second surface in contact with the semiconductor die and the second package substrate, respectively.

13. The semiconductor package of claim 12, further comprising a redistribution structure interposed between the first package substrate and the semiconductor die.

14. The semiconductor package of claim 12, wherein the second package substrate includes a heat sink.

15. The semiconductor package of claim 12, wherein, when viewed from the top, the plurality of structures form one of: a checkboard pattern; a two-dimensional array; a single pillar; a number of pillars arranged in parallel; or a ring.

16. The semiconductor package of claim 12, wherein the heat dissipation layer further comprises a fluid tunnel with an inlet and an outlet.

17. The semiconductor package of claim 16, wherein the inlet and outlet are formed on opposite sides of the heat dissipation layer, respectively.

18. The semiconductor package of claim 16, wherein the inlet and outlet are formed on a same side of the heat dissipation layer.

19. A method for fabricating semiconductor packages, comprising:
bonding one or more semiconductor dies to a first package substrate, wherein the first package substrate is on a first side of the one or more semiconductor dies;
forming a heat dissipation layer on a second side of the one or more semiconductor dies, wherein the heat dissipation layer comprises a plurality of structures, and wherein each of the plurality of structures is formed of a high-k dielectric material; and
coupling a second package substrate to the one or more semiconductor dies, with the heat dissipation layer interposed between the second package substrate and the one or more semiconductor dies, wherein each of the plurality of structures has a first surface and a second surface in contact with the one or more semiconductor dies and the second package substrate, respectively.

20. The method of claim 19, wherein, when viewed from the top, the plurality of structures form one of: a checkboard pattern; a two-dimensional array; a single pillar; a number of pillars arranged in parallel; or a ring.
